(19) United States
(12) Patent Application Publication
(10) Pub. No.: US 2025/0158352 A1
(43) Pub. Date: May 15, 2025

(54) LASER MODULE

(71) Applicant: HAMAMATSU PHOTONICS K.K., Hamamatsu-shi (JP)

(72) Inventors: Atsushi SUGIYAMA, Hamamatsu-shi (JP); Tadataka EDAMURA, Hamamatsu-shi (JP)

(73) Assignee: HAMAMATSU PHOTONICS K.K., Hamamatsu-shi (JP)

(21) Appl. No.: 18/947,169

(22) Filed: Nov. 14, 2024

(30) Foreign Application Priority Data
Nov. 15, 2023 (JP) 2023-194522

(51) Int. Cl. H01S 5/0239; H01S 5/023; H01S 5/14; H01S 5/34

(52) U.S. Cl. CPC H01S 5/0239; H01S 5/023; H01S 5/141; H01S 5/3402

(57) ABSTRACT

The laser module includes a housing with a bottom wall on which a mount member is placed, and accommodates a QCL element, a diffraction grating unit, a first lens holder, a second lens holder, and the mount member. The mount member includes a first mounting section for mounting the first lens holder, a second mounting section for mounting the QCL element and a temperature sensor, a third mounting section for mounting the second lens holder, and a fourth mounting section for mounting the diffraction grating unit. At least a second surface of the second mounting section facing the bottom wall is fixed to the bottom wall via a medium having a higher thermal conductivity than air and filled between the second surface and the bottom wall.

### TECHNICAL FIELD

The present disclosure relates to a laser module.

### CROSS-REFERENCE TO RELATED APPLICATION

This application claims the benefit of priority from Japanese Patent Application No. 2023-194522, filed Nov. 15, 2023, the entire contents of which are incorporated herein by reference.

### BACKGROUND

An external cavity laser module (hereinafter simply referred to as “laser module”) including a quantum cascade laser element (hereinafter referred to as “QCL element”), a diffraction grating unit including a movable diffraction grating, and two lenses disposed on both sides of the QCL element is known (see, for example, Patent Document 1 (Japanese Unexamined Patent Application Publication No. 2023-44956)). In the above laser module, a mount member that mounts the QCL element, the diffraction grating unit, and the two lens holders holding the two lenses is disposed on a bottom wall of a box-shaped housing.

### SUMMARY

In the laser module described above, there is a need to reduce the size of the housing. Additionally, to enhance the reliability of the laser module, stabilization of temperature control within the laser module is required.

Therefore, one aspect of the present disclosure aims to provide a laser module that can improve the stability of temperature control within the laser module while suppressing the increase in size of the laser module.

The present disclosure includes the following laser modules [1] to [8].

[1] A laser module including:
a quantum cascade laser element;
a diffraction grating unit including a movable diffraction grating that constitutes an external resonator for the quantum cascade laser element;
a first lens holder disposed on a side opposite to a side where the movable diffraction grating is positioned with respect to the quantum cascade laser element and configured to hold a first lens for allowing a first output light from the quantum cascade laser element to pass through;
a second lens holder disposed between the quantum cascade laser element and the movable diffraction grating and configured to hold a second lens for allowing a second output light from the quantum cascade laser element and a light returning from the movable diffraction grating to the quantum cascade laser element to pass through;
a mount member that mounts the quantum cascade laser element, the diffraction grating unit, the first lens holder, and the second lens holder; and
a housing that includes a bottom wall on which the mount member is placed and accommodates the quantum cascade laser element, the diffraction grating unit, the first lens holder, the second lens holder, and the mount member;
wherein the mount member includes a first mounting section, a second mounting section, a third mounting section, and a fourth mounting section sequentially arranged from the first lens holder side to the diffraction grating unit side along a first direction in which the first lens holder and the second lens holder face each other;
wherein the first mounting section includes:
   a first mounting surface on which the first lens holder is mounted; and
   a first surface facing the bottom wall on an opposite side of the first mounting surface,
wherein the second mounting section includes:
   a second mounting surface on which the quantum cascade laser element and a temperature sensor are mounted; and
   a second surface facing the bottom wall on an opposite side of the second mounting surface,
wherein the third mounting section includes:
   a third mounting surface on which the second lens holder is mounted; and
   a third surface facing the bottom wall on an opposite side of the third mounting surface,
wherein the fourth mounting section includes:
   a fourth mounting surface on which the diffraction grating unit is mounted, and
wherein at least the second surface is fixed to the bottom wall via a medium having a higher thermal conductivity than air and filled between the second surface and the bottom wall.

In the laser module of [1], the medium having a higher thermal conductivity than air is filled between at least the second surface of the mount member and the bottom wall, and the mount member (second surface) is fixed to the bottom wall via the medium. By filling the medium having a higher thermal conductivity than air directly below the second mounting section where the quantum cascade laser element (QCL element), which tends to generate heat, is mounted, the heat dissipation from the second surface to the housing (bottom wall) can be effectively improved. This allows for the stabilization of temperature control within the laser module. To further enhance heat dissipation, it is conceivable to place a cooling element such as a Peltier module between the mount member and the bottom wall. However, using such a cooling element would require space not only for the cooling element itself but also for the wiring for the cooling element, potentially increasing the size of the housing. In the above laser module, the mount member is directly placed on the bottom wall via the medium filled in the gap between at least the second surface and the bottom wall without using such a cooling element, thereby suppressing the increase in size of the housing. Therefore, according to the above laser module, it is possible to improve the stability of temperature control within the laser module while suppressing the increase in size of the laser module.

[2] The laser module according to [1],
wherein the medium is formed of a thermosetting resin adhesive.

According to the configuration of [2], by using a resin adhesive as the medium, it is possible to suppress the mount member from peeling off from the bottom wall due to the difference in thermal expansion between the mount member and the bottom wall. Additionally, since the resin adhesive is thermosetting, there is no need to provide space (e.g., a gap for allowing light to cure the resin adhesive) required when using a light-curing resin adhesive, thereby enabling the reduction in size of the housing.

[3] The laser module according to [1] or [2],
wherein the medium is also filled between the first surface and the bottom wall, and between the third surface and the bottom wall; and
wherein the first surface and the third surface are fixed to the bottom wall via the medium.

According to the configuration of [3], by placing the medium not only directly below the second mounting section where the QCL element is mounted (between the second surface and the bottom wall) but also directly below the first mounting section and the third mounting section adjacent to the second mounting section (between the first surface and the third surface and the bottom wall), the heat dissipation from the mount member to the bottom wall can be further improved. As a result, the temperature control within the laser module can be further stabilized.

[4] The laser module according to any one of [1] to [3],
wherein the fourth mounting section includes a fourth surface facing the bottom wall on an opposite side of the fourth mounting surface and continuous with the third surface;
wherein the medium is also filled between the fourth surface and the bottom wall; and
wherein the fourth surface is fixed to the bottom wall via the medium.

According to the configuration of [4], the heat dissipation from the mount member to the bottom wall can be further improved, and consequently, the temperature control within the laser module can be further stabilized.

[5] The laser module according to any one of [1] to [4],
wherein the housing includes:
   a rear side wall facing the diffraction grating unit in the first direction; and
   a front side wall facing the first lens holder in the first direction, and
wherein a distance between the rear side wall and the mount member in the first direction is shorter than a distance between the front side wall and the mount member in the first direction.

According to the configuration of [5], by placing the mount member closer to the rear side wall than to the front side wall, it is possible to reduce the likelihood of the first lens holder contacting the front side wall and being damaged. Additionally, after placing the mount member with the QCL element and the diffraction grating unit mounted (fixed) on the bottom wall to manufacture the laser module, there may be cases where the alignment of the lenses (i.e., the position adjustment of the lens holders relative to the mount member) is performed. In such cases, the above configuration allows for securing the distance between the first lens holder and the front side wall, making it easier to align the first lens (adjust the position of the first lens holder relative to the mount member).

[6] The laser module according to [5],
wherein, at an outer edge on the rear side wall side of a bottom surface of the mount member facing the bottom wall, a notch extending along the outer edge is provided.

According to the configuration of [6], even if a raised portion such as a weld bead is formed near the connection between the bottom wall and the rear side wall during the manufacturing of the laser module, the notch provided along the outer edge of the bottom surface of the mount member on the rear side wall side can avoid or reduce interference between the mount member and the raised portion. This makes it easier to place the mount member closer to the rear side wall.

[7] The laser module according to any one of [1] to [6],
wherein, at an outer edge of a bottom surface of the mount member facing the bottom wall, a notch or recess extending along the outer edge is provided; and
wherein the medium is placed in at least a part of a space between the notch or recess and the bottom wall.

According to the configuration of [7], by allowing a part of the medium to enter the notch or recess, the fixing strength of the mount member to the bottom wall via the medium can be improved. Additionally, since the fixing strength of the mount member to the bottom wall can be improved using the notch or recess, the amount of medium required to ensure the fixing strength of the mount member to the bottom wall (i.e., the thickness of the medium placed between the bottom surface of the mount member (including at least the second surface) and the bottom wall) can be reduced, further improving the heat dissipation from the mount member to the bottom wall.

[8] The laser module according to any one of [1] to [7], further comprising an insulating submount disposed on the second mounting surface, and
wherein the quantum cascade laser element and the temperature sensor are disposed on the second mounting section via the submount.

According to the configuration of [8], by placing the QCL element and the temperature sensor on the insulating submount, the QCL element and the temperature sensor can be electrically separated (insulated). This prevents electrical noise caused by the driving current of the QCL element from being detected by the temperature sensor, enabling highly accurate and stable temperature measurement by the temperature sensor. As a result, based on the measurement values of the temperature sensor, more highly stable temperature control of the laser module can be achieved. Additionally, by mounting the QCL element and the temperature sensor on the submount and unitizing them, it is possible to facilitate the pre-inspection of the QCL element and the mounting of the QCL element on the mount member. Furthermore, since it is possible to form metal patterns on the surface of the submount, the electrical connection configuration for supplying the driving current to the QCL element and the electrical connection configuration for obtaining the output signal of the temperature sensor can be easily realized. Moreover, since the QCL element (semiconductor substrate) and the temperature sensor are reliably insulated by the insulating submount, the degree of freedom in selecting the adhesive material for bonding the QCL element and the temperature sensor to the submount can be improved.

According to one aspect of the present disclosure, it is possible to provide a laser module that can improve the stability of temperature control within the laser module while suppressing the increase in size of the laser module.

### BRIEF DESCRIPTION OF THE DRAWINGS

FIG. 1 is a perspective view of a laser module according to an embodiment.

FIG. 2 is a cross-sectional view of the central part in the width direction Y of the laser module of FIG. 1.

FIG. 3 is a perspective view of the mount member with each component mounted except for the first lens holder and the second lens holder.

FIG. 4A is a diagram showing an example of a notch provided at the outer edge of the bottom surface of the mount member, and FIG. 4B is a diagram showing an example of a recess provided at the outer edge of the bottom surface of the mount member.

FIG. 5 is a plan view showing an example of the electrical connection configuration of the QCL element and the temperature sensor disposed on the upper part of the second mounting section of the mount member.

### DETAILED DESCRIPTION

Hereinafter, an embodiment of the present disclosure will be described in detail with reference to the drawings. In the following description, the same or equivalent elements are denoted by the same reference numerals, and redundant descriptions are omitted. Additionally, terms such as “upper” and “lower” are used for convenience based on the state shown in the drawings.

### Overall Configuration of the Laser Module

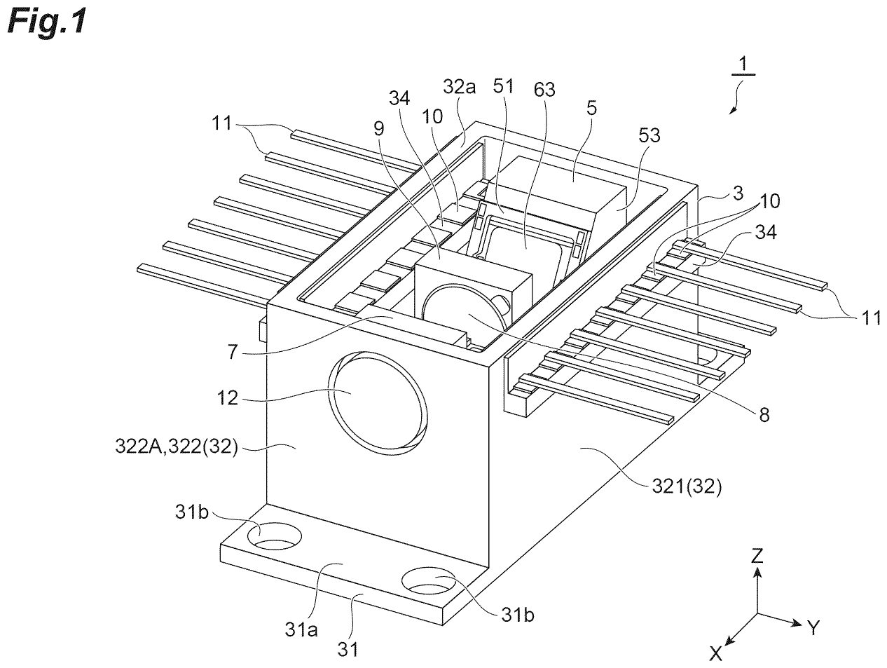

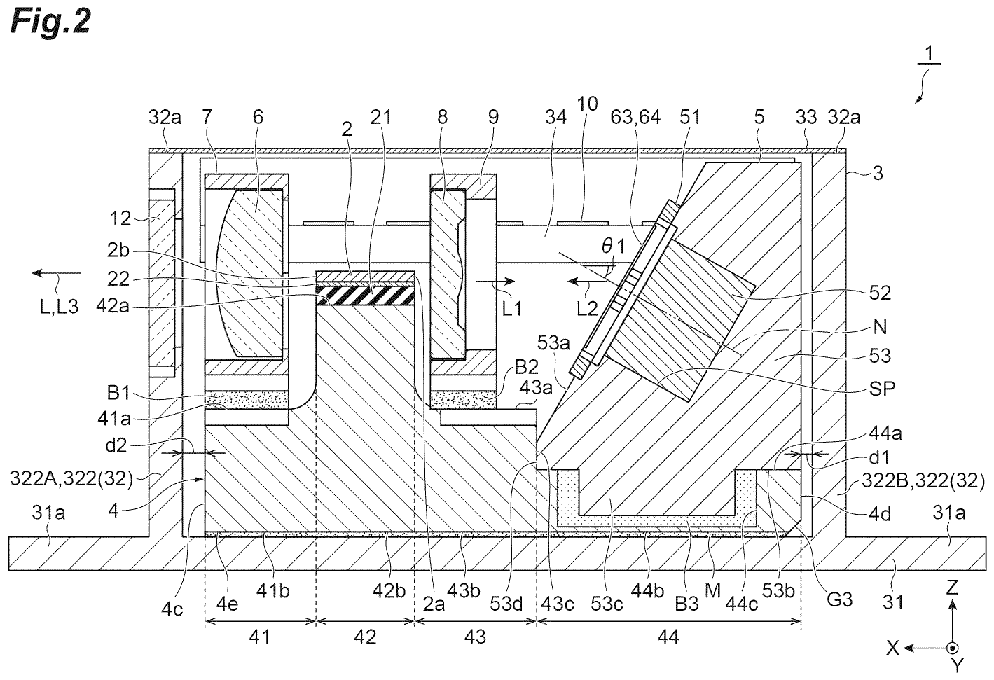

As shown in FIGS. 1 and 2, the laser module 1 includes a quantum cascade laser element (hereinafter referred to as “QCL element”) 2 and a housing 3 that hermetically accommodates the QCL element 2. The laser module 1 is a tunable wavelength light source with a variable wavelength of output light (laser light L). The laser module 1 can be used for, for example, biological measurement of glucose or the like, measurement of an absorption spectrum of an analysis target such as VOC gas (volatile organic compound) having a light absorption band. For example, when measuring such an absorption spectrum, the analysis target contained in a light-transmissive container is placed between the laser module 1 and a photodetector (not shown). The laser module 1 performs wavelength sweeping within a predetermined wavelength range (e.g., mid-infrared region) by rapidly changing the wavelength of the output light (laser light L). As a result, the absorption spectrum is calculated based on the detection results of the photodetector. The analysis target may be in any state of gas, liquid, or solid.

The housing 3 accommodates the QCL element 2, a mount member 4, a diffraction grating unit 5, a lens 6 (first lens) held by a lens holder 7 (first lens holder), and a lens 8 (second lens) held by a lens holder 9 (second lens holder). The housing 3 includes a bottom wall 31, a side wall 32, and a top wall 33. In FIG. 1, illustration of the top wall 33 is omitted.

The bottom wall 31 is a rectangular plate-like member. The bottom wall 31 is formed of a metal material such as copper tungsten. The mount member 4 is placed on the bottom wall 31. For convenience, the longitudinal direction of the bottom wall 31 is referred to as the front-rear direction X (first direction), the short direction of the bottom wall 31 is referred to as the width direction Y, and the direction perpendicular to the bottom wall 31 (i.e., the direction orthogonal to both the front-rear direction X and the width direction Y) is referred to as the vertical direction Z. The front-rear direction X is the direction in which the lens holders 7 and 9 face each other. In other words, the front-rear direction X is the direction in which the end faces 2a and 2b of the QCL element 2 face each other (i.e., the direction perpendicular to the end faces 2a and 2b) and is also the direction along the optical axis of the laser light L emitted from the QCL element 2.

The side wall 32 is erected on the bottom wall 31. The side wall 32 is formed in an annular shape (rectangular annular shape in this embodiment) to surround an internal space accommodating the QCL element 2 and other components when viewed from the vertical direction Z. In this embodiment, the side wall 32 is formed in a rectangular tubular shape. The side wall 32 is formed of a metal material such as Kovar. The side wall 32 is, for example, a Kovar frame plated with Ni/Au. In this embodiment, the side wall 32 is provided at the central part in the front-rear direction X. On both sides of the bottom wall 31 in the front-rear direction X, protruding portions 31a extending outward beyond the side walls 32 are formed. Screw holes 31b for attaching the housing 3 (bottom wall 31) to other components are provided at a portion corresponding to four corners of the bottom wall 31 in the protruding portions 31a.

The top wall 33 (see FIG. 2) is a member that closes the opening of the side walls 32 on a side opposite to the bottom wall 31 side. The top wall 33 has a rectangular plate shape. The top wall 33 is formed of, for example, the same metal material as the side walls 32 (e.g., Kovar). The top wall 33 is joined to an end portion 32a of the side wall 32 opposite to the bottom wall 31 side by, for example, seam welding, with the interior of the housing 3 replaced with vacuum or nitrogen.

Each of the pair of first side walls 321 extending in the front-rear direction X of the side walls 32 is provided with a protruding wall 34 projecting both outward and inward of the first side wall 321. The protruding wall 34 is an eave-like member extending along the front-rear direction X above the central position of the first side wall 321 in the vertical direction Z. On the upper surface of the protruding wall 34, a plurality of flat electrode terminals 10 (seven on each protruding wall 34, totaling 14) for supplying power to each component (e.g., QCL element 2, movable diffraction grating 51 (coil 65), etc.) inside the housing 3 are arranged. Each electrode terminal 10 penetrates through the first side wall 321. As shown in FIG. 1, the portions of each electrode terminal 10 located outside the first side wall 321 are electrically connected to lead pins 11, which are electrically connected to an external power source. Each electrode terminal 10 is arranged at approximately equal intervals along the front-rear direction X on the upper surface of the protruding wall 34. Each lead pin 11 is arranged at approximately equal intervals along the front-rear direction X above the portions of each electrode terminal 10 located outside the first side wall 321. The portions of each electrode terminal 10 located inside the first side wall 321 are electrically connected to each component inside the housing 3 via wires (not shown). Through the wires, electrode terminals 10, and lead pins 11, power is supplied from the external power source to each component.

The second side wall 322 extending along the width direction Y of the side walls 32 includes a front side wall 322A facing the lens 6 (lens holder 7) and a rear side wall 322B facing the diffraction grating unit 5. The front side wall 322A is provided with a light emission window 12 for allowing the laser light L emitted from one end face 2b of the QCL element 2 to pass through. The light emission window 12 is formed of, for example, a material (e.g., germanium) that transmits laser light L in the mid-infrared region. For example, the light emission window 12 is formed in a circular plate shape and fixed to a circular opening formed in the front side wall 322A.

As shown in FIG. 2, the laser module 1 includes a mount member 4 that mounts the QCL element 2, the diffraction grating unit 5, and the lens holders 7, 9 inside the housing 3. The mount member 4 is formed of, for example, a material with excellent thermal conductivity, such as copper.

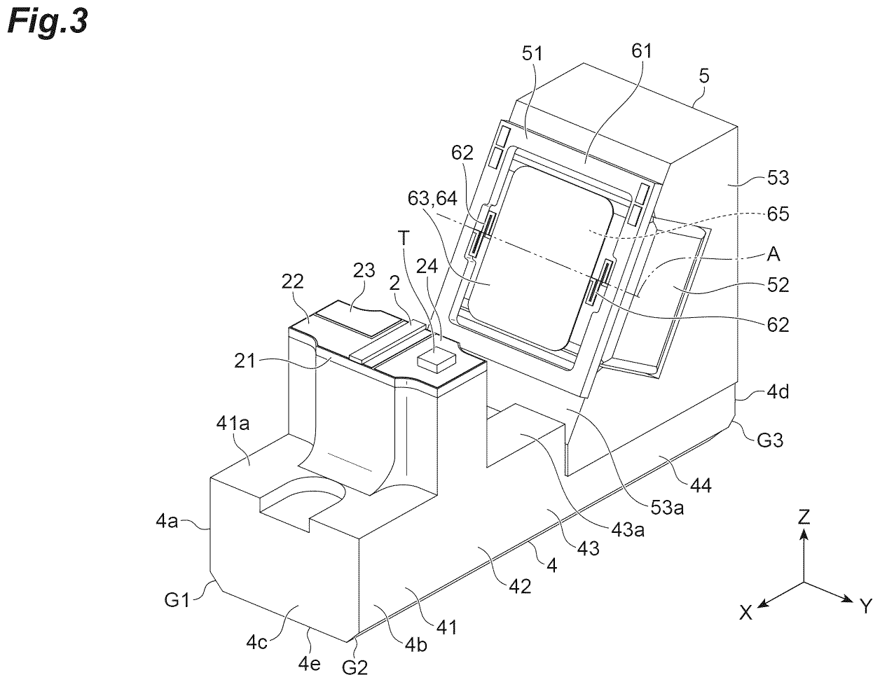

The mount member 4 is an elongated member in the front-rear direction X. The mount member 4 includes a first mounting section 41, a second mounting section 42, a third mounting section 43, and a fourth mounting section 44. The first mounting section 41, the second mounting section 42, the third mounting section 43, and the fourth mounting section 44 are sequentially arranged from the lens holder 7 side to the diffraction grating unit 5 side along the front-rear direction X. As shown in FIGS. 2 and 3, the mount member 4 includes a pair of side surfaces 4a, 4b extending along the front-rear direction X (intersecting the width direction Y), a front surface 4c facing the front side wall 322A, a rear surface 4d facing the rear side wall 322B, and a bottom surface 4e facing the bottom wall 31.

The first mounting section 41 includes an upper surface 41a (first mounting surface) on which the lens holder 7 is mounted and a first surface 41b facing the bottom wall 31 on the opposite side of the upper surface 41a.

The second mounting section 42 includes an upper surface 42a (second mounting surface) on which the QCL element 2 and the temperature sensor T are mounted and a second surface 42b facing the bottom wall 31 on the opposite side of the upper surface 42a.

The third mounting section 43 includes an upper surface 43a (third mounting surface) on which the lens holder 9 is mounted and a third surface 43b facing the bottom wall 31 on the opposite side of the upper surface 43a.

The fourth mounting section 44 includes an upper surface 44a (fourth mounting surface) on which the diffraction grating unit 5 is mounted and a fourth surface 44b facing the bottom wall 31 on the opposite side of the upper surface 44a.

The first surface 41b, the second surface 42b, the third surface 43b, and the fourth surface 44b are continuously flush with each other, forming the bottom surface 4e of the mount member 4.

The first mounting section 41 and the third mounting section 43 have the same thickness in the vertical direction Z. That is, the height position of the upper surface 41a of the first mounting section 41 matches the height position of the upper surface 43a of the third mounting section 43 relative to the bottom surface 4e. The lens holder 7 is adhesively fixed to the upper surface 41a of the first mounting section 41 via an adhesive layer B1 made of a light-curing resin (e.g., UV-curing resin). Similarly, the lens holder 9 is adhesively fixed to the upper surface 43a of the third mounting section 43 via an adhesive layer B2 made of a light-curing resin (e.g., UV-curing resin).

The second mounting section 42 is provided between the first mounting section 41 and the third mounting section 43. The second mounting section 42 is thicker in the vertical direction Z than the first mounting section 41 and the third mounting section 43. That is, the upper surface 42a of the second mounting section 42 is positioned higher than the upper surfaces 41a and 43a of the first and third mounting sections 41 and 43. The QCL element 2 is fixed to the upper surface 42a of the second mounting section 42 via a submount 21.

The submount 21 is an insulating member disposed on the upper surface 42a and formed in a plate shape with a predetermined thickness. The submount 21 is formed of, for example, aluminum nitride (AlN). The submount 21 mounts the QCL element 2 and the temperature sensor T. The temperature sensor T is, for example, a thermistor. The QCL element 2 and the temperature sensor T are disposed on the second mounting section 42 via the submount 21.

The fourth mounting section 44 is thinner than the first mounting section 41 and the third mounting section 43. That is, the upper surface 44a of the fourth mounting section 44 is positioned lower than the upper surfaces 41a and 43a of the first and third mounting sections 41 and 43. The fourth mounting section 44 is provided with a non-through hole (placement hole 44c) that opens to the upper surface 44a but does not penetrate the fourth surface 44b. As shown in FIG. 2, the diffraction grating unit 5 is fixed to the fourth mounting section 44 using a resin adhesive B3, such as a thermosetting resin, with a protruding portion 53c, which is part of a yoke 53 as described later, inserted into the placement hole 44c.

The QCL element 2 has end faces 2a and 2b facing each other in the front-rear direction X. The end face 2a faces the lens 8, and the end face 2b faces the lens 6. The QCL element 2 emits light in the mid-infrared region (e.g., 4 μm to 12 μm) from each of the end faces 2a and 2b. The end faces 2a and 2b are flat surfaces (cleaved surfaces) perpendicular to the front-rear direction X, and the optical axis of the laser light L emitted from the QCL element 2 is along the front-rear direction X. For example, the QCL element 2 is composed of a semiconductor substrate and a semiconductor layer (including an active layer) laminated on the semiconductor substrate. In this embodiment, the QCL element 2 is disposed on the submount 21 with the semiconductor substrate positioned downward and the semiconductor layer positioned upward. The semiconductor layer included in the QCL element 2 has a laminated structure including an active layer composed of multiple quantum well layers (e.g., InGaAs) and multiple quantum barrier layers (e.g., InAlAs) and a pair of cladding layers (e.g., InP) disposed on both sides of the active layer. In this embodiment, the lamination direction of the laminated structure matches the vertical direction Z. The QCL element 2 may include multiple active layers with different central wavelengths and a pair of cladding layers, and in this case, it can emit broadband light as described above. The end face 2a may be provided with an anti-reflection coating, and the end face 2b functioning as a resonant surface may be provided with a low-reflection coating.

The lens 6 is disposed on the side opposite to the side where the movable diffraction grating 51 (diffraction grating unit 5) is positioned with respect to the QCL element 2. That is, the lens 6 is disposed at a position facing the end face 2b of the QCL element 2. The lens 6 is, for example, an aspherical lens made of zinc selenide (ZnSe). The surface of the lens 6 may be provided with an anti-reflection coating. The lens 6 allows the light L3 (first output light) emitted from the end face 2b of the QCL element 2 to pass through. For example, the lens 6 collimates the light L3. The light L3 collimated by the lens 6 passes through the light emission window 12 and is output to the outside as output light (laser light L).

The lens 8 is disposed between the end face 2a of the QCL element 2 and the movable diffraction grating 51 (diffraction grating unit 5). That is, the lens 8 is disposed at a position facing the end face 2a of the QCL element 2. For example, the lens 8 is formed of chalcogenide glass and has a central portion functioning as a short-focus microlens with a diameter of several millimeters or less. The lens 8 allows the light L1 (second output light) emitted from the end face 2a of the QCL element 2 and the light L2 returning from the movable diffraction grating 51 to the QCL element 2 to pass through. The lens 8 collimates the light L1.

The lens holders 7 and 9 have a substantially rectangular parallelepiped shape. The lens holders 7 and 9 are provided in a cylindrical shape surrounding the side surfaces of the lenses 6 and 8. The lenses 6 and 8 are supported (held) by the lens holders 7 and 9 via resin adhesives or the like.

The diffraction grating unit 5 includes a movable diffraction grating 51, a magnet 52, and a yoke 53. The movable diffraction grating 51 is formed in a substantially plate shape. The magnet 52 is disposed on the side opposite to the QCL element 2 with respect to the movable diffraction grating 51. The movable diffraction grating 51 is fixed to the yoke 53, and the magnet 52 is housed within the yoke 53. The movable diffraction grating 51, the magnet 52, and the yoke 53 are integrated to form a single unit.

The light L1 collimated by the lens 8 is incident on the movable diffraction grating 51 of the diffraction grating unit 5. The movable diffraction grating 51 diffracts and reflects the incident light L1, returning a part of the light L1 (specific wavelength light L2) to the end face 2a of the QCL element 2 via the lens 8. That is, the movable diffraction grating 51 constitutes an external resonator for the light L1 emitted from the end face 2a of the QCL element 2. In this embodiment, a Littrow-type external resonator is formed by the movable diffraction grating 51 and the end face 2b of the QCL element 2. This allows the laser module 1 to amplify the specific wavelength light L2 and output it to the outside as output light (laser light L).

Additionally, the movable diffraction grating 51 can rapidly change the orientation of the diffraction grating portion 64 that diffracts and reflects the incident light L1. This allows the wavelength of the light L2 returning from the movable diffraction grating 51 to the end face 2a of the QCL element 2 to be variable, and consequently, the wavelength of the output light (laser light L) of the laser module 1 is variable.

As shown in FIG. 3, the movable diffraction grating 51 includes a support portion 61, a pair of connecting portions 62, a movable portion 63, a diffraction grating portion 64, and a coil 65. The movable diffraction grating 51 is configured as a MEMS device that swings (rotates) the movable portion 63 around the axis A. A MEMS device is a device formed using microfabrication technology (patterning, etching, etc.) called MEMS technology, including semiconductor devices formed using semiconductor microfabrication technology.

The support portion 61 is a flat frame body having a rectangular shape in plan view. The support portion 61 supports the movable portion 63 via a pair of connecting portions 62. Each connecting portion 62 is a flat member having a rectangular bar shape in plan view and extends along the axis A while bending. Each connecting portion 62 connects the movable portion 63 to the support portion 61 on the axis A so that the movable portion 63 can swing around the axis A. The movable portion 63 is positioned inside the support portion 61. The movable portion 63 can swing around the axis A as described above. The support portion 61, the connecting portions 62, and the movable portion 63 are, for example, integrally formed by being fabricated on a single SOI (Silicon on Insulator) substrate.

The diffraction grating portion 64 is provided on the surface of the movable portion 63 on the side of the QCL element 2. The diffraction grating portion 64 has multiple grating grooves (not shown) and diffracts and reflects the light L1 emitted from the QCL element 2. The diffraction grating portion 64 is provided on the surface of the movable portion 63 and includes a resin layer with a diffraction grating pattern formed on it and a metal layer provided over the surface of the resin layer along the diffraction grating pattern. Alternatively, the diffraction grating portion 64 may be composed only of a metal layer with a diffraction grating pattern formed on it, provided on the movable portion 63. The diffraction grating pattern can be, for example, a blazed grating with a sawtooth cross-section as in this embodiment, a binary grating with a rectangular cross-section, or a holographic grating with a sinusoidal cross-section. The diffraction grating pattern is formed on the resin layer by, for example, nanoimprint lithography. The metal layer is, for example, a metal reflective film made of gold, formed by vapor deposition.

The coil 65 is made of a metal material such as copper and has a damascene structure embedded in a groove formed on the surface of the movable portion 63. The coil 65 is a drive coil for driving the movable diffraction grating 51 (i.e., swinging the movable portion 63).

The magnet 52 generates a magnetic field (magnetic force) acting on the coil 65. The magnet 52 is, for example, a neodymium magnet (permanent magnet) formed in a substantially rectangular parallelepiped shape.

The yoke 53 amplifies the magnetic force of the magnet 52 and forms a magnetic circuit together with the magnet 52. The yoke 53 includes an inclined surface 53a, a lower surface 53b, a protruding portion 53c, and a positioning surface 53d.

As shown in FIG. 2, the inclined surface 53a is inclined with respect to the end face 2a of the QCL element 2. By fixing the movable diffraction grating 51 on such an inclined surface 53a, the normal N of the diffraction grating portion 64 of the movable diffraction grating 51 can be inclined with respect to the end face 2a. In this example, the diffraction grating portion 64 is inclined to face one side (top wall 33 side) in the vertical direction Z, but it may be inclined to face the other side (bottom wall 31 side) in the vertical direction Z. The inclination angle of the inclined surface 53a (i.e., the angle θ1 of the normal N with respect to the front-rear direction X when viewed from the width direction Y) is set according to the oscillation wavelength of the QCL element 2, the number of grooves in the diffraction grating portion 64, and the blaze angle, etc. For example, when the oscillation wavelength is in the 7 μm band and the number of grooves is 150 grooves/mm, the angle θ1 is set to about 30 degrees.

The yoke 53 is formed in a substantially U-shape (inverted C-shape) when viewed from the width direction Y, defining a placement space SP that opens to the inclined surface 53a. The magnet 52 is placed in this placement space SP, and the magnet 52 is housed within the yoke 53. The yoke 53 surrounds the magnet 52 when viewed from the width direction Y. The movable diffraction grating 51 is fixed to the inclined surface 53a at the edge of the support portion 61 to cover the opening of the placement space SP.

The lower surface 53b faces the upper surface 44a of the fourth mounting section 44. The lower surface 53b is provided with a protruding portion 53c projecting downward. The positioning surface 53d is perpendicular to the front-rear direction X, connecting the inclined surface 53a and the lower surface 53b. The positioning surface 53d abuts a side surface 43c of the third mounting section 43 (the surface connecting the upper surface 43a of the third mounting section 43 and the upper surface 44a of the fourth mounting section 44). This provides positional alignment of the diffraction grating unit 5 in the front-rear direction X.

When a current flows through the coil 65 in the movable diffraction grating 51, a Lorentz force is generated in a predetermined direction on the electrons flowing through the coil 65 due to the magnetic field formed by the magnet 52 and the yoke 53. This causes the coil 65 to experience a force in a predetermined direction. By controlling the direction or magnitude of the current flowing through the coil 65, the movable portion 63 (diffraction grating portion 64) can be swung around the axis A. Additionally, by flowing a current with a frequency corresponding to the resonant frequency of the movable portion 63 through the coil 65, the movable portion 63 can be swung at a high speed at the resonant frequency level (e.g., at a frequency of 1 kHz or higher). Thus, the coil 65, the magnet 52, and the yoke 53 function as an actuator unit for swinging the movable portion 63.

### Detailed Configuration of the Mount Member

As shown in FIG. 2, the bottom surface 4e of the mount member 4 is fixed to the bottom wall 31 via a medium M filled between the bottom surface 4e and the bottom wall 31. The medium M is formed of a material with a higher thermal conductivity than air. For example, the medium M is formed of a thermosetting resin adhesive.

As shown in FIG. 2, the distance dl between the rear side wall 322B and the mount member 4 (fourth mounting section 44) in the front-rear direction X is shorter than the distance d2 between the front side wall 322A and the mount member 4 (first mounting section 41) in the front-rear direction X.

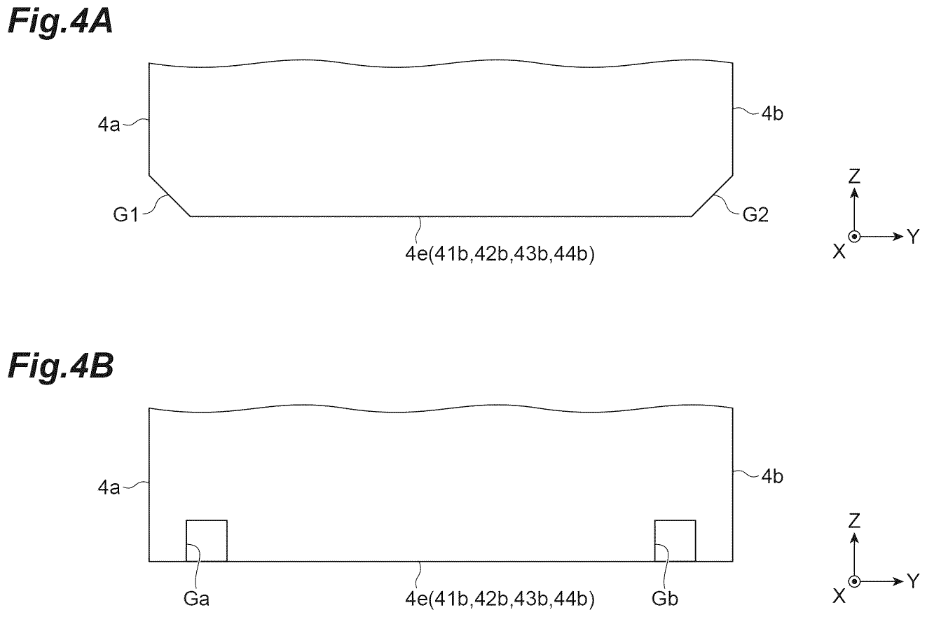

As shown in FIGS. 3 and 4A, the outer edge of the bottom surface 4e of the mount member 4 is provided with notches G1, G2, and G3 (notch grooves) extending along the outer edge. In this embodiment, a notch G1 extending in the front-rear direction X is provided on the outer edge of the side surface 4a side of the bottom surface 4e. A notch G2 extending in the front-rear direction X is provided on the outer edge of the side surface 4b side of the bottom surface 4e. A notch G3 extending in the width direction Y is provided on the outer edge of the rear surface 4d side of the bottom surface 4e (see FIGS. 2 and 3). No notch is provided on the outer edge of the front surface 4c side of the bottom surface 4e.

Here, at least a part of the space between the notches G1, G2, G3 and the bottom wall 31 is filled with the medium M. In this embodiment, a resin pool formed of a part of the medium M is formed in at least a part of the space between the notches G1, G2, G3 and the bottom wall 31. For example, during the manufacturing of the laser module 1, the medium M is applied to the bottom wall 31 or the bottom surface 4e of the mount member 4, and the mount member 4 is pressed against the bottom wall 31, causing the medium M to be compressed in the vertical direction Z and stretched in the front-rear direction X or the width direction Y. This causes a part of the medium M to protrude (escape) into the space between the notches G1, G2, G3 and the bottom wall 31. This protruding part of the medium M forms the aforementioned resin pool.

Note that instead of the notches G1, G2, G3 described above, recesses (recess grooves) may be formed at the outer edge of the bottom surface 4e of the mount member 4. For example, as shown in FIG. 4B, a recess Ga extending in the front-rear direction X may be provided at the outer edge of the side surface 4a side of the bottom surface 4e, inside the corner where the bottom surface 4e intersects with the side surface 4a. Similarly, a recess Gb extending in the front-rear direction X may be provided at the outer edge of the side surface 4b side of the bottom surface 4e, inside the corner where the bottom surface 4e intersects with the side surface 4b.

### Electrical Connection Configuration of the QCL Element and Temperature Sensor

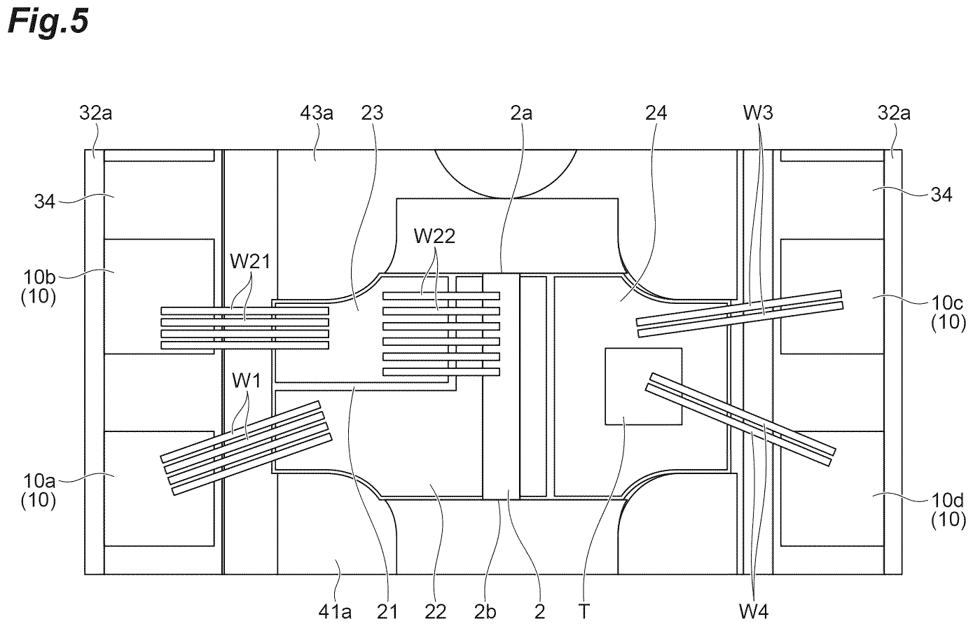

As shown in FIGS. 3 and 5, three separated metal patterns 22, 23, 24 (metal thin films) are formed on the submount 21. The metal pattern 22 includes a portion exposed on one side of the QCL element 2 in the width direction Y (opposite to the side where the temperature sensor T is disposed) and a portion disposed below the QCL element 2 and in contact with the QCL element 2 (e.g., the surface opposite to the semiconductor layer side of the semiconductor substrate). The metal pattern 22 functions as the cathode electrode of the QCL element 2. The metal pattern 23 includes a portion exposed on one side of the QCL element 2 in the width direction Y (opposite to the side where the temperature sensor T is disposed). The metal pattern 24 includes a portion exposed on the other side of the QCL element 2 in the width direction Y (the side where the temperature sensor T is disposed) and a portion disposed below the temperature sensor T and in contact with the temperature sensor T. The metal pattern 24 functions as one electrode (positive or negative electrode) connected to the temperature sensor T.

The laser module 1 includes metal wirings W1, W21, W22, W3, W4, each consisting of one or more wires. For example, each of the metal wirings W1, W21 consists of four wire groups, the metal wiring W22 consists of six wire groups, and each of the metal wirings W3, W4 consists of two wire groups.

One end of the metal wiring WI is connected to one electrode terminal 10a positioned on one side of the QCL element 2 in the width direction Y. The other end of the metal wiring W1 is connected to the metal pattern 22. One end of the metal wiring W21 is connected to another electrode terminal 10b positioned on one side of the QCL element 2 in the width direction Y. The other end of the metal wiring W21 is connected to the metal pattern 23. One end of the metal wiring W22 is connected to the metal pattern 23. The other end of the metal wiring W22 is connected to the anode electrode of the QCL element 2 (e.g., an electrode provided on the semiconductor layer). The lead pins 11 (corresponding to the electrode terminals 10a, 10b), the electrode terminals 10a, 10b, the metal wirings W1, W21, W22, and the metal patterns 22, 23 form an electrical connection configuration (current path) for supplying a driving current from the external power source to the QCL element 2.

One end of the metal wiring W3 is connected to one electrode terminal 10c positioned on the other side of the QCL element 2 in the width direction Y. The other end of the metal wiring W3 is connected to the metal pattern 24. One end of the metal wiring W4 is connected to another electrode terminal 10d positioned on the other side of the QCL element 2 in the width direction Y. The other end of the metal wiring W4 is connected to the other electrode of the temperature sensor T. The lead pins 11 (corresponding to the electrode terminals 10c, 10d), the electrode terminals 10c, 10d, the metal wirings W3, W4, and the metal pattern 24 form an electrical connection configuration (current path) for obtaining the output signal (e.g., resistance change) of the temperature sensor T.

### Effects of the Present Embodiment

In the laser module 1 described above, the medium M with a higher thermal conductivity than air is filled between at least the second surface 42b of the mount member 4 and the bottom wall 31, and the mount member 4 (second surface 42b) is fixed to the bottom wall 31 via the medium M. By filling the medium M with a higher thermal conductivity than air directly below the second mounting section 42 where the QCL element 2, which tends to generate heat, is mounted, the heat dissipation from the second surface 42b to the housing 3 (bottom wall 31) can be effectively improved. This allows for the stabilization of temperature control within the laser module 1. More specifically, even if the temperature inside the laser module 1 rises, the heat can be suitably dissipated from the second surface 42b to the housing 3, preventing the temperature inside the laser module 1 from rising excessively and keeping the temperature within a certain range.

To further enhance heat dissipation, it is conceivable to place a cooling element such as a Peltier module between the mount member 4 (bottom surface 4e) and the bottom wall 31. However, using such a cooling element would require space not only for the cooling element itself but also for the wiring for the cooling element, potentially increasing the size of the housing 3. In the laser module 1, the mount member 4 is directly placed on the bottom wall 31 via the medium M filled in the gap between at least the second surface 42b and the bottom wall 31 without using such a cooling element, thereby suppressing the increase in size of the housing 3. Therefore, according to the laser module 1, it is possible to improve the stability of temperature control within the laser module 1 while suppressing the increase in size of the laser module 1.

The medium M is formed of a thermosetting resin adhesive. According to this configuration, by using a resin adhesive as the medium M, it is possible to suppress the mount member 4 from peeling off from the bottom wall 31 due to the difference in thermal expansion between the mount member 4 and the bottom wall 31. Additionally, since the resin adhesive is thermosetting, there is no need to provide space (e.g., a gap for allowing light to cure the resin adhesive) required when using a light-curing resin adhesive, thereby enabling the reduction in size of the housing 3.

As shown in FIG. 2, the medium M is also filled between the first surface 41b and the bottom wall 31, and between the third surface 43b and the bottom wall 31, and the first surface 41b and the third surface 43b are fixed to the bottom wall 31 via the medium M. According to this configuration, by placing the medium M not only directly below the second mounting section 42 where the QCL element 2 is mounted (between the second surface 42b and the bottom wall 31) but also directly below the first mounting section 41 and the third mounting section 43 adjacent to the second mounting section 42 (between the first surface 41b and the third surface 43b and the bottom wall 31), the heat dissipation from the mount member 4 to the bottom wall 31 can be further improved. As a result, the temperature control within the laser module 1 can be further stabilized.

As shown in FIG. 2, the medium M is also filled between the fourth surface 44b and the bottom wall 31, and the fourth surface 44b is fixed to the bottom wall 31 via the medium M. According to this configuration, the heat dissipation from the mount member 4 to the bottom wall 31 can be further improved, and consequently, the temperature control within the laser module 1 can be further stabilized.

As a method of fixing the fourth mounting section 44 to the bottom wall 31, it is conceivable to form the placement hole 44c as a through hole in the vertical direction Z and fix the fourth mounting section 44 and the diffraction grating unit 5 (protruding portion 53c) to the bottom wall 31 via the resin adhesive B3 filled in the placement hole 44c. However, in such a configuration, voids generated within the resin adhesive B3 may cause the fourth mounting section 44 and the diffraction grating unit 5 (protruding portion 53c) to peel off from the bottom wall 31. In contrast, as shown in FIG. 2, by configuring the placement hole 44c as a non-through hole, forming the fourth surface 44b facing the bottom wall 31 on the entire lower surface of the fourth mounting section 44, and fixing the fourth surface 44b to the bottom wall 31 via the medium M, it is possible to avoid the occurrence of the above problem.

As shown in FIG. 2, the distance d1 between the rear side wall 322B and the mount member 4 in the front-rear direction X is shorter than the distance d2 between the front side wall 322A and the mount member 4 in the front-rear direction X. According to this configuration, by placing the mount member 4 closer to the rear side wall 322B than to the front side wall 322A, it is possible to reduce the likelihood of the lens holder 7 (or the surface of the lens 6 held by the lens holder 7 facing the light emission window 12) contacting the front side wall 322A and being damaged. Additionally, after placing the mount member 4 with the QCL element 2 and the diffraction grating unit 5 mounted (fixed) on the bottom wall 31 to manufacture the laser module 1, there may be cases where the alignment of the lenses 6, 8 (i.e., the position adjustment of the lens holders 7, 9 relative to the mount member 4) is performed. In such cases, the above configuration (i.e., the configuration where the mount member 4 is placed in the housing 3 such that “d1<d2”) allows for securing the distance between the lens holder 7 and the front side wall 322A, making it easier to align the lens 6 (adjust the position of the lens holder 7 relative to the mount member 4).

As shown in FIGS. 2 and 3, at an outer edge on the rear side wall 322B side of the bottom surface 4e of the mount member 4, a notch G3 extending in the width direction Y along the outer edge is provided.

According to this configuration, even if a raised portion such as a weld bead is formed near the connection between the bottom wall 31 and the rear side wall 322B during the manufacturing of the laser module 1, the notch G3 provided along the outer edge of the bottom surface 4e (fourth surface 44b) on the rear side wall 322B side can avoid or reduce interference between the mount member 4 and the raised portion. This makes it easier to place the mount member 4 closer to the rear side wall 322B.

As shown in FIGS. 2, 3, and 4A, notches G1, G2, G3 extending along the outer edge are provided on the outer edge of the bottom surface 4e of the mount member 4 (in this embodiment, on all outer edges except the front surface 4c side). Additionally, the medium M is placed in at least a part of the space between the notches G1, G2, G3 and the bottom wall 31. According to this configuration, by allowing a part of the medium M to enter the notches G1, G2, G3, the fixing strength of the mount member 4 to the bottom wall 31 via the medium M can be improved. For example, by forming the aforementioned resin pool in the space between the notches G1, G2, G3 and the bottom wall 31, the fixing strength of the mount member 4 to the bottom wall 31 can be enhanced. Additionally, since the fixing strength of the mount member 4 to the bottom wall 31 can be improved using the notches G1, G2, G3 (i.e., a part of the medium M entering the space formed by the notches G1, G2, G3), the amount of medium M required to ensure the fixing strength of the mount member 4 to the bottom wall 31 (i.e., the thickness of the medium M placed between the bottom surface 4e of the mount member 4 and the bottom wall 31) can be reduced, further improving the heat dissipation from the mount member 4 to the bottom wall 31.

Note that as shown in FIG. 4B, the same effect can be obtained by forming recesses Ga, Gb instead of the notches G1, G2. However, from the viewpoint of enhancing the fixing strength between the bottom surface 4e and the bottom wall 31 by increasing the area of the continuous region where the bottom surface 4e and the bottom wall 31 are fixed via the medium M, it is preferable to provide the recesses Ga, Gb as close as possible to the outer edge of the bottom surface 4e. Additionally, from this viewpoint, it is preferable to provide the notches G1, G2 rather than the recesses Ga, Gb at the outer edge of the bottom surface 4e.

As shown in FIGS. 2 and 3, an insulating submount 21 is disposed on the upper surface 42a of the second mounting section 42. The QCL element 2 and the temperature sensor T are disposed on the second mounting section 42 via the submount 21. According to this configuration, by placing the QCL element 2 and the temperature sensor T on the insulating submount 21, the QCL element 2 and the temperature sensor T can be electrically separated (insulated). This prevents electrical noise caused by the driving current of the QCL element 2 from being detected by the temperature sensor T, enabling highly accurate and stable temperature measurement by the temperature sensor T. As a result, based on the measurement values of the temperature sensor T, more highly stable temperature control of the laser module 1 (e.g., cooling control of the housing 3 to lower the temperature inside the laser module 1) can be achieved. Additionally, by mounting the QCL element 2 and the temperature sensor T on the submount 21 and unitizing them, it is possible to facilitate the pre-inspection of the QCL element 2 and the mounting of the QCL element 2 on the mount member 4. Furthermore, as shown in FIGS. 3 and 5, since it is possible to form metal patterns 22, 23, 24 on the surface of the submount 21, the electrical connection configuration for supplying the driving current to the QCL element 2 and the electrical connection configuration for obtaining the output signal of the temperature sensor T can be easily realized. Moreover, since the QCL element 2 (semiconductor substrate) and the temperature sensor T are reliably insulated by the insulating submount 21, the degree of freedom in selecting the adhesive material for bonding the QCL element 2 and the temperature sensor T to the submount 21 can be improved. In other words, since the QCL element 2 and the temperature sensor T can be insulated by the submount 21, there is no need to use an insulating adhesive to insulate the QCL element 2 and the temperature sensor T. As a result, it is possible to bond the QCL element 2 and the temperature sensor T to the submount 21 using a highly thermally conductive adhesive regardless of whether it is insulating or conductive. This effectively enhances the heat dissipation from the QCL element 2 and the temperature sensor T to the housing 3 (bottom wall 31) via the submount 21 and the mount member 4.

### Modifications

The present disclosure is not limited to the above embodiment. Various materials and shapes can be adopted for each component, not limited to the materials and shapes described above. Additionally, some components included in the laser module 1 according to the above embodiment may be omitted or changed as appropriate. For example, although several characteristic configurations and effects exhibited by each configuration of the laser module 1 were described in the above embodiment, the laser module according to the present disclosure does not necessarily need to be configured to exhibit all the effects described in the above embodiment. The laser module may be configured to exhibit only some of the effects described in the above embodiment. In the latter case, the laser module only needs to include the essential configurations to exhibit at least some of the effects, and the configurations that are not essential to exhibit those effects may be omitted or changed as appropriate.

For example, the medium M may be disposed only between a part of the bottom surface 4e (including at least the second surface 42b) and the bottom wall 31. However, by disposing the medium M between the entire bottom surface 4e and the bottom wall 31 as in the present embodiment, the heat dissipation from the mount member 4 to the bottom wall 31 can be effectively improved.

Additionally, the positions and shapes of the notches or recesses are not limited to the examples shown in FIGS. 4A and 4B. In the example of FIG. 4A, the notch G1 is formed in a triangular cross-section, but it may be formed in a rectangular cross-section, for example. Each of the notches G1, G2, G3 may be omitted, or a notch or recess may be provided on the outer edge of the front surface 4c side of the bottom surface 4e. However, by providing the notches G1, G2 along the longitudinal direction (front-rear direction X) as in the present embodiment, it is possible to form resin pools extending long in the front-rear direction X along the notches G1, G2 on both sides in the width direction Y, thereby effectively improving the fixing strength of the mount member 4 to the bottom wall 31.

What is claimed is:

1. A laser module comprising:
a quantum cascade laser element;
a diffraction grating unit including a movable diffraction grating that constitutes an external resonator for the quantum cascade laser element;
a first lens holder disposed on a side opposite to a side where the movable diffraction grating is positioned with respect to the quantum cascade laser element and configured to hold a first lens for allowing a first output light from the quantum cascade laser element to pass through;
a second lens holder disposed between the quantum cascade laser element and the movable diffraction grating and configured to hold a second lens for allowing a second output light from the quantum cascade laser element and a light returning from the movable diffraction grating to the quantum cascade laser element to pass through;
a mount member that mounts the quantum cascade laser element, the diffraction grating unit, the first lens holder, and the second lens holder; and
a housing that includes a bottom wall on which the mount member is placed and accommodates the quantum cascade laser element, the diffraction grating unit, the first lens holder, the second lens holder, and the mount member;
wherein the mount member includes a first mounting section, a second mounting section, a third mounting section, and a fourth mounting section sequentially arranged from the first lens holder side to the diffraction grating unit side along a first direction in which the first lens holder and the second lens holder face each other;
wherein the first mounting section includes:
a first mounting surface on which the first lens holder is mounted; and
a first surface facing the bottom wall on an opposite side of the first mounting surface,
wherein the second mounting section includes:
a second mounting surface on which the quantum cascade laser element and a temperature sensor are mounted; and
a second surface facing the bottom wall on an opposite side of the second mounting surface,
wherein the third mounting section includes:
a third mounting surface on which the second lens holder is mounted; and
a third surface facing the bottom wall on an opposite side of the third mounting surface,
wherein the fourth mounting section includes:
a fourth mounting surface on which the diffraction grating unit is mounted, and
wherein at least the second surface is fixed to the bottom wall via a medium having a higher thermal conductivity than air and filled between the second surface and the bottom wall.

2. The laser module according to claim 1,
wherein the medium is formed of a thermosetting resin adhesive.

3. The laser module according to claim 1,
wherein the medium is also filled between the first surface and the bottom wall, and between the third surface and the bottom wall; and
wherein the first surface and the third surface are fixed to the bottom wall via the medium.

4. The laser module according to claim 1,
wherein the fourth mounting section includes a fourth surface facing the bottom wall on an opposite side of the fourth mounting surface and continuous with the third surface;
wherein the medium is also filled between the fourth surface and the bottom wall; and
wherein the fourth surface is fixed to the bottom wall via the medium.

5. The laser module according to claim 1,
wherein the housing includes:
a rear side wall facing the diffraction grating unit in the first direction; and
a front side wall facing the first lens holder in the first direction, and
wherein a distance between the rear side wall and the mount member in the first direction is shorter than a distance between the front side wall and the mount member in the first direction.

6. The laser module according to claim 5,
wherein, at an outer edge on the rear side wall side of a bottom surface of the mount member facing the bottom wall, a notch extending along the outer edge is provided.

7. The laser module according to claim 1,
wherein, at an outer edge of a bottom surface of the mount member facing the bottom wall, a notch or recess extending along the outer edge is provided; and
wherein the medium is placed in at least a part of a space between the notch or recess and the bottom wall.

8. The laser module according to claim 1, further comprising an insulating submount disposed on the second mounting surface, and
wherein the quantum cascade laser element and the temperature sensor are disposed on the second mounting section via the submount.
